(19) United States
(12) Patent Application Publication
(10) Pub. No.: US 2005/0169029 A1
(43) Pub. Date: Aug. 4, 2005

(54) Method and apparatus for loading additional content data

(75) Inventors: Limonov Alexandre, Seoul (KR); Jea Yong Yoo, Seoul (KR); Woo Seong Yoon, Namyangloo-si (KR)

Correspondence Address: LEE, HONG, DEGERMAN, KANG & SCHMADEKA, 14th Floor, 801 S. Figueroa Street, Los Angeles, CA, 90017, US

(73) Assignee: LG Electronics Inc.

(21) Appl. No.: 11/019,793

(22) Filed: Dec. 20, 2004

(30) Foreign Application Priority Data
Nov. 19, 2003 (KR) 10-2003-0093760

(51) Int. Cl. G11C 15/00

(52) U.S. Cl. 365/49

(57) ABSTRACT

Method and apparatus for loading additional content data in a memory that are to be presented in synchronization with main audio/video data recorded on an optical disk are disclosed. According to the method of loading additional content data in accordance with the present invention, all of persistent additional content data are selected among the additional content data and are then loaded in the memory contiguously. And then, updatable additional content data block is loaded in a separate region of the memory from the persistent additional content data while the updatable additional content data block loaded previously are deleted

### FOREIGN PRIORITY

The present invention claims priority under 35 U.S.C. 119 on Korean Application No. 10-2003-093760 filed Dec. 19, 2003; the contents of which are incorporated by reference in their entirety.

### BACKGROUND OF THE INVENTION

1. Field of the Invention

The present invention relates to a method and apparatus for effectively loading additional content data in a memory that are to be presented in synchronization with main audio/video data recorded on a recording medium.

2. Description of the Related Art

High-density optical disks capable of storing large amounts of high-quality digital audio/video (A/V) data have been widely used. The DVD (digital versatile disk) is one example of these high-density optical disks.

The DVD includes a data stream recording area in which digital video contents are stored and a navigation data recording area in which navigation data required for playback control of the video contents is stored.

When a DVD is loaded into a DVD reproducing apparatus, the DVD reproducing apparatus first reads the navigation data recorded in the navigation data recording area and stores the navigation data in an internal memory. The DVD reproducing apparatus then reproduces the video contents recorded in the data stream recording area using the navigation data.

In the meantime, the development of new interactive DVDs is being progressing. Unlike the DVD, the interactive DVD contains additional content data related to the main A/V data recorded thereon. An enhanced DVD (called E-DVD hereinafter) is a kind of interactive DVDs.

The additional contents related to the main A/V can be available on the disk or from content provider (CP) servers through communication networks like the Internet. In the E-DVD, the additional content data that enables interactivity of the main A/V data is called enhanced navigation data (called ENAV data hereinafter).

The additional contents should be loaded or buffered in a memory in the optical disk apparatus before their presentation so that they are presented in synchronization with the main A/V data. Practically, all of the additional contents cannot, however, be preloaded in a memory at a time due to the memory size. Methods of loading the additional contents in a memory partially and sequentially are needed to effectively utilize the memory.

### SUMMARY OF THE INVENTION

It is an object of the present invention to provide a method and apparatus for effectively loading the additional content data in a memory depending on the kinds of additional content data, specifically, for loading persistent additional content data and updatable additional content data into a separate region of the memory.

In accordance with the present invention, there is provided a method of loading additional content data into storage means in a disk apparatus, in which additional content data associated with main content data recorded on a disk recording medium are examined, persistent additional content data are loaded into the storage means contiguously, the main content data; and loading at least one block of updatable additional content data included in the additional content data is loaded into a separate area of the storage means from the area in which the persistent additional content data are loaded.

In accordance with the present invention, there is provided a recording medium comprising main content data including at least video data; and additional content data that are to be presented in synchronization with the main content data, wherein the additional content data include information on whether or not the additional content data is updatable after being loaded into storage means.

According to a first embodiment of the method of loading additional content data into storage means in accordance with the present invention, after the persistent additional content data are loaded into the storage means contiguously, one block of updatable additional content data is loaded into the storage means in contiguity with the loaded persistent additional content data. If presentation of the updatable additional content data block loaded previously is completed, the updatable additional content data block is replaced by a next updatable additional content data block to be presented subsequently.

According to a second embodiment of the method of loading additional content data into storage means in accordance with the present invention, after the persistent additional content data are loaded into the storage means contiguously, two blocks of updatable additional content data are loaded into the storage means at a time in contiguity with the loaded persistent additional content data. If presentation of the second updatable additional content data block loaded previously is started, the first updatable additional content data block in the storage means is deleted, and then a new updatable additional content data block to be presented subsequently among the remained updatable additional content data is loaded into the storage means.

According to a third embodiment of the method of loading additional content data into storage means in accordance with the present invention, after the persistent additional content data are loaded into the storage means contiguously, three blocks of updatable additional content data are loaded at a time in the storage means in contiguity with the persistent additional content data. If presentation of the third updatable additional content data block loaded previously begins, the first updatable additional content data block is deleted, and then a new updatable additional content data block to be presented subsequently among the remained updatable additional content data is loaded into the storage means. In addition to seamless forward playback, this embodiment enables seamless reverse playback because the second updatable additional content data block is preserved in the storage means during presentation of the third updatable additional content data block.

### BRIEF DESCRIPTION OF THE DRAWINGS

The above features and other advantages of the present invention will be more clearly understood from the following detailed description taken in conjunction with the accompanying drawings, in which:

FIG. 1 illustrates a block diagram of an optical disk reproducing apparatus in accordance with the present invention;

FIG. 2 illustrates a volume space of an optical disk in accordance with the present invention;

FIG. 3 illustrates a structure of additional content data;

FIG. 4 illustrates an example of additional content data file in accordance with the present invention;

FIG. 5 illustrates schematic diagram showing a sequence of loading additional content data in a memory; and

FIGS. 6 to 8 illustrate three embodiments of the method of loading additional content data in a memory in accordance with the present invention.

### DETAILED DESCRIPTION OF THE PREFERRED EMBODIMENTS

In order that the invention may be fully understood, preferred embodiments thereof will now be described with reference to the accompanying drawings.

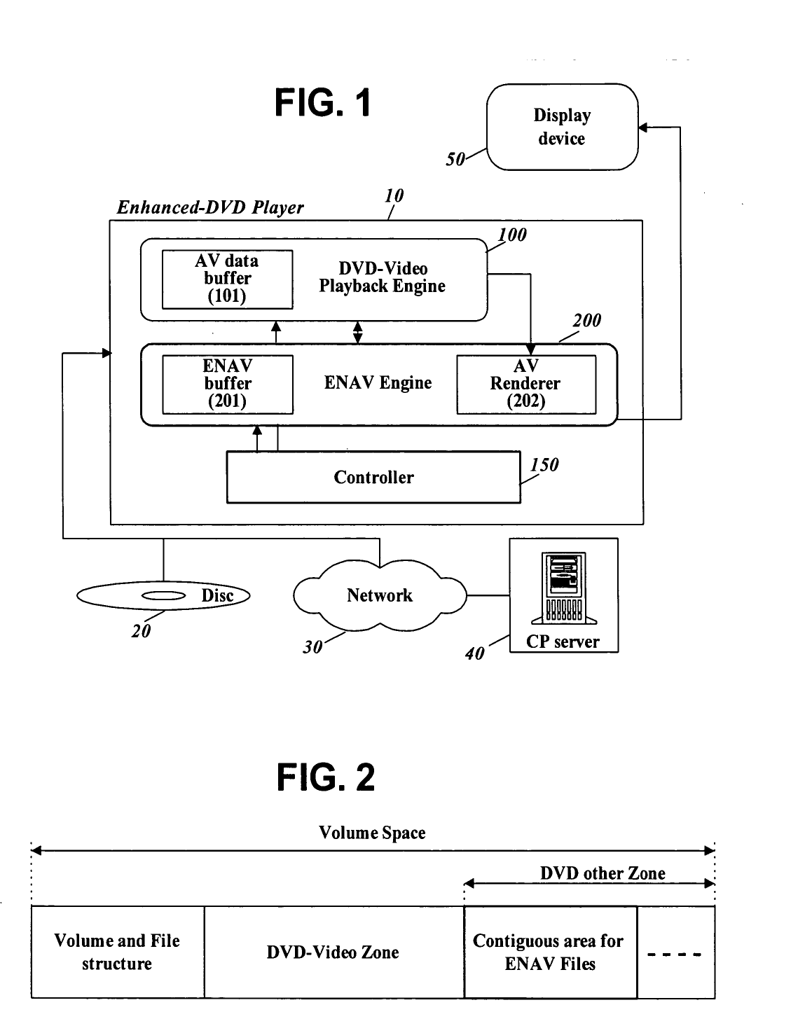

FIG. 1 depicts a block diagram of an optical disk reproducing apparatus in accordance with the present invention that is capable of reproducing E-DVDs. The optical disk reproducing apparatus includes, among other things, a DVD-video playback engine 100 for decoding A/V data from an optical disk 20 or E-DVD; an ENAV engine 200 for interpreting and/or decoding additional content data such as ENAV data; and a controller 150 for controlling disk reproduction operations. The DVD-video playback engine 100 includes an A/V data buffer 101, and the ENAV engine 200 includes an ENAV buffer 201 and an A/V renderer 202. The function of the A/V renderer 202 is to combine DVD-video data and ENAV picture, generate video data in a predetermined format, and output the generated video data to an external display device 50.

After an optical disk with interactive features like E-DVD is loaded into the optical disk reproducing apparatus 10, the apparatus 10 can connect a predetermined CP server 40 through a communication network 30 such as the Internet by using navigation information stored in the optical disk.

In general, the E-DVD has a volume space shown in FIG. 2 that includes a volume and file structure zone 1 for storing volume and file structure information, a DVD-video zone 2 for storing main digital A/V data stream, a DVD other zone 3 for storing additional content data, that is, ENAV data files.

The main A/V data recorded on the DVD-video zone 2 is read into the A/V data buffer 101 and are then decoded for presentation by the DVD-video playback engine 100. The additional content data (called ENAV data hereinafter) that are read out from the DVD other zone 3 or supplied from CP server 40 are read into the ENAV buffer 201, which usually consists of SRAM of 36 Mbytes.

There are two kinds of ENAV data. One is persistent ENAV data that are preserved in the ENAV buffer 201 after loaded, since the persistent ENAV data are required continually in synchronization with playback of the main A/V data. The files including the persistent ENAV data may be compressed and recorded on the E-DVD as an archive file. The other one is updatable ENAV data that are used for a short period of time in reproduction of parts of the main A/V data. Therefore, updatable ENAV data are usually loaded in the ENAV buffer 201 block by block. Once presentation is completed, updatable ENAV data block(s) are deleted and new updatable ENAV data block(s) are loaded in the ENAV buffer 201.

The persistent ENAV data includes XHTML formatted pages such as startup page, menu page, and error message page. Markup page constituting elements such as cascading style sheets (CSS) 1 and 2 for style defining how to display HTML elements, fonts, and images such as logo, styling image, and background image are also included in the persistent ENAV data. Moreover, audio data such as effect audio, background audio, animated logo, and animation of startup and menu pages are included in the persistent ENAV data.

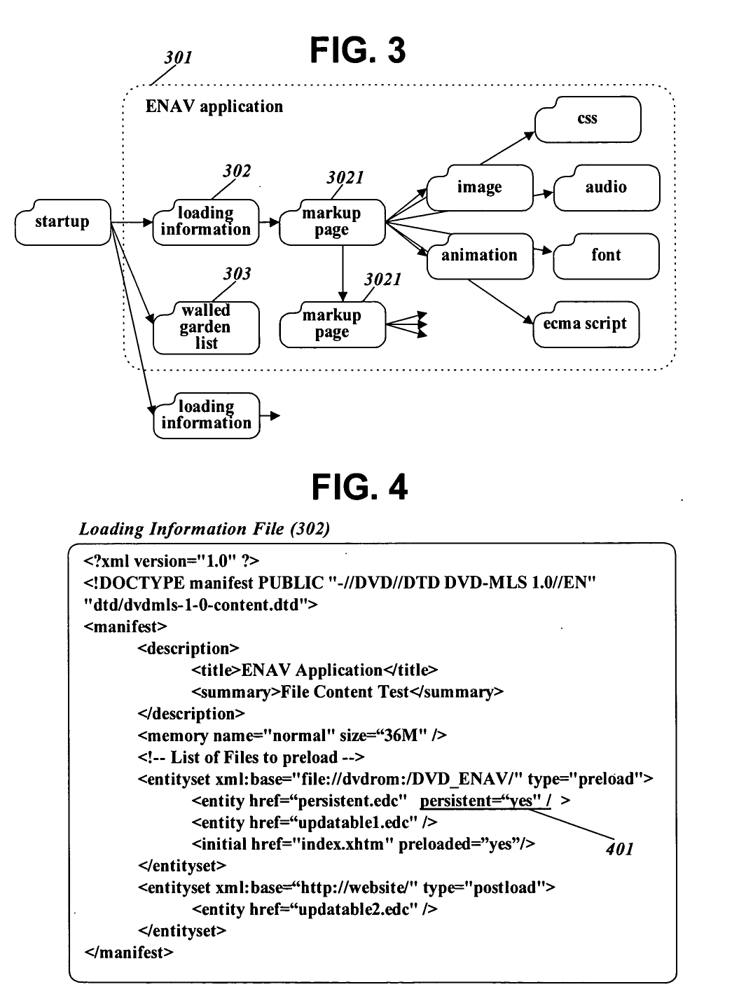

FIG. 3 illustrates an ENAV data structure. An ENAV data includes a startup page as a root and a plurality of ENAV applications. One ENAV application 301 includes, among other things, loading information file 302 to be loaded in the ENAV buffer 201 and walled garden list 303 for defining address map of the access-permitted external servers for obtaining remotely available data such as markup pages and content data.

The loading information file 302 includes one or more markup pages 3021, each contains interactive content structure, synchronization with DVD-video data, and display timing information. Each markup page 3021 can be linked to image, animation, CSS, audio, fonts and ECMA (European Computer Manufacturers Association) scripts. It is desirable that each ENAV application does not exceed the size of the ENAV buffer 201.

As shown in FIG. 4, a loading information file 302 contains whether markup pages linked are persistent or not. If a markup page is persistent, a script 401 (persistent=“yes”) is added to the markup page. In the case, the ENAV engine 200 in the optical disk reproducing apparatus of FIG. 1 determines the markup page loaded as persistent markup page. If it is determined that there is no script 401, the markup page is regarded as updatable markup page. Instead, a script, for example, persistent=“no” may be explicitly used to indicate updatable markup pages.

When ENAV data of FIG. 3 and FIG. 4 are loaded in the ENAV buffer 201, the ENAV engine 200 loads persistent ENAV data and updatable ENAV data into separate regions of the ENAV buffer 201.

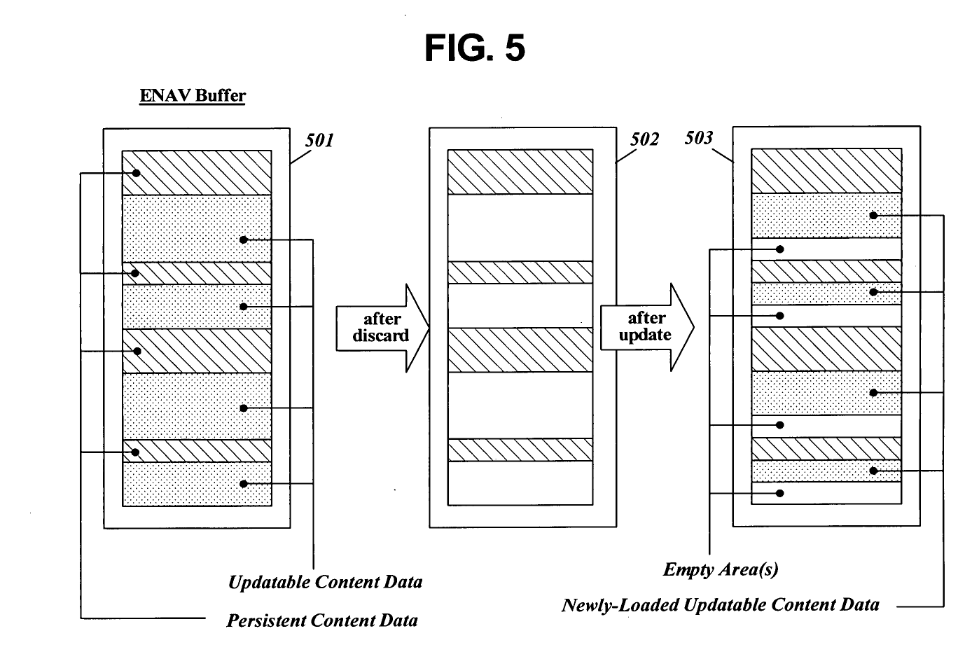

Instead of separately loading persistent ENAV data and updatable ENAV data, they may be loaded sequentially in the ENAV buffer 201, as shown in FIG. 5. To be specific, in a conventional method of FIG. 5, after persistent ENVA data and updatable ENAV data are loaded sequentially in the ENAV buffer 201 regardless of the kind of ENAV data (501), the updatable ENVA data are deleted in the ENAV buffer 201 when their presentation is completed (502). And then, new updatable ENAV data are loaded into available regions of the ENAV buffer 201 (503). When new updatable ENVA data segment does not match the available regions in size, available region of the ENAV buffer 201 is broken into small, non-contiguous blocks so that blank spaces arise and data associated with one markup page are loaded fragmented in the ENAV buffer 201, in the embodiment of FIG. 5.

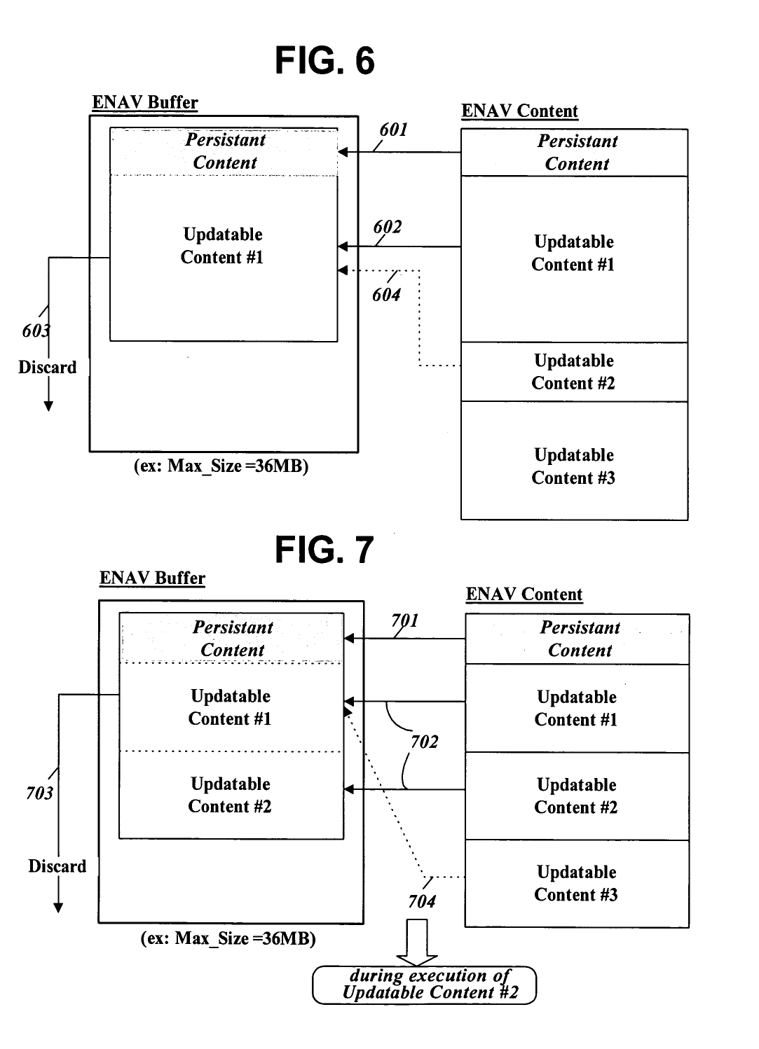

FIG. 6 illustrates a first embodiment of the method of loading persistent and updatable ENVA data into separate regions in the ENAV buffer. As shown in FIG. 6, all of the persistent ENAV data are selected first among ENAV data, which are read out from the optical disk 20 or on a remote CP server, and are then loaded in the ENAV buffer 201 (601). And then the first block of updatable ENAV data is read into the ENAV buffer 201 just after the persistent ENAV data (602). The block unit in which updatable ENAV data is loaded may be file or markup page including video, audio, and text data or a group of files or markup web pages.

After the first block of updatable ENAV data is decoded and presented in synchronization with the main A/V data by the ENAV engine 200, the updatable ENAV data block is deleted in the ENAV buffer 201 (603) and the next block of updatable ENAV data is loaded just after the persistent ENAVE data (604).

In the first embodiment, while the persistent ENAV data are preserved in the ENAV buffer 201 until playback of the main A/V data is completed, a plurality of updatable ENAV data are loaded block by block in the ENAV buffer 201 just after the persistent ENAV data. As a result, available regions of the ENAV buffer 201 are not broken into small, non-contiguous blocks and thereby persistent ENAV data are not fragmented in the ENAV buffer 201 as in the conventional method of FIG. 5.

FIG. 7 illustrates a second embodiment of the method of loading persistent and updatable ENAV data into separate regions in the ENAV buffer 201. As shown in FIG. 7, all of the persistent ENAV data are loaded in the ENAV buffer 201 (701), and the two blocks of updatable ENAV data are then read sequentially into the ENAV buffer 201 just after the persistent ENAV data (702).

After the first block of updatable ENAV data in the ENAV buffer 201 is decoded and presented in synchronization with the main A/V data by the ENAV engine 200, the first block of updatable ENAV data is deleted in the ENAV buffer 201 (703). And then, while the second block of updatable ENAV is decoded for presentation, the third block of updatable ENAV data is loaded in the ENAV buffer 201 (704). If the third block of updatable ENAV data is smaller than the first block in size, the third block of updatable ENAV data is loaded in the region where the first block of updatable ENAV data has been loaded. If not, the third block of updatable ENAV data is loaded in the ENAV buffer 201 just after the second block of updatable ENAV data. The load and delete operations of ENAV data into the ENAV buffer 201 are performed under control of the controller 150.

The second embodiment enables seamless forward playback of E-DVD 20 because the next block of updatable ENAV data to be played back subsequently is already loaded in the ENAV buffer 201.

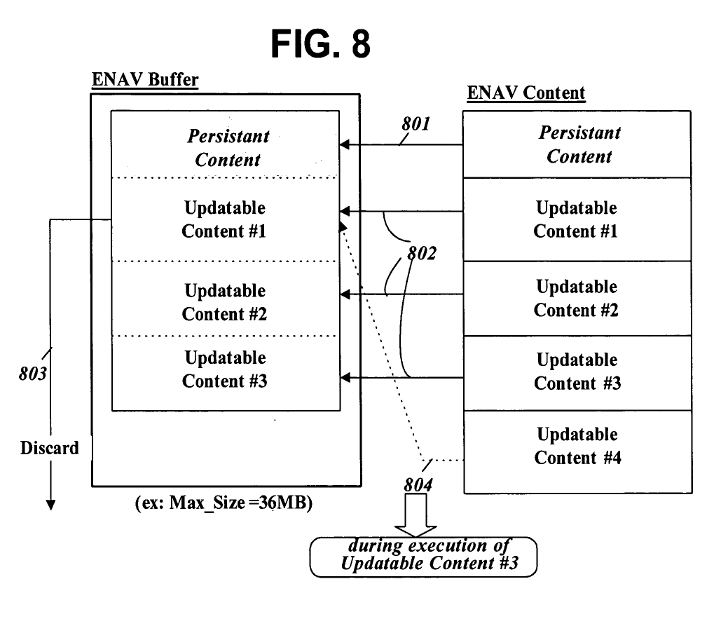

FIG. 8 illustrates a third embodiment of the method of loading persistent and updatable ENAV data into separate regions in the ENAV buffer 201. As shown in FIG. 8, all of persistent ENAV data are loaded in the ENAV buffer 201 (801), and the three blocks of updatable ENAV data are then read sequentially into the ENAV buffer 201 just after the persistent ENAV data (802).

After the first and second blocks of updatable ENAV data are decoded and presented in synchronization with the main A/V data by the ENAV engine 200, the first block of updatable ENAV data is deleted in the ENAV buffer 201 (803), while the second block of updatable ENAV data is preserved. The second block of updatable ENAV data is supposed to be deleted immediately after presentation of the third block of updatable ENAV data is completed. And then, during presentation of the third block of updatable ENAV data loaded, the fourth block of updatable ENAV data is loaded in the ENAV buffer 201 (804). If the fourth block of updatable ENAV data is smaller than the first block of updatable ENAV data, the fourth block of updatable ENAV data is loaded in the region where the first block of updatable ENAV data has been loaded. If there is no available region between updatable ENAV data blocks, the fourth block of updatable ENAV data is loaded in the ENAV buffer 201 just after the last, that is, the third block of updatable ENAV data loaded before. In this way, the subsequent blocks of updatable ENAV data are loaded in the ENAV buffer 201 sequentially.

In addition to seamless forward playback, the third embodiment enables seamless reverse playback of E-DVD 20 because the preceding and subsequent blocks of updatable ENAV data are already loaded in the ENAV buffer 201.

When an optical disk with interactive features is play backed, the present invention described in detail, disclosed with respect to a limited number of embodiments, enables to provide an effective way of preventing available regions of an additional content data buffer from being broken into small, non-contiguous regions, thereby preventing additional content data from being resided fragmented in the additional content buffer.

While the invention has been disclosed with respect to a limited number of embodiments, those skilled in the art, having the benefit of this disclosure, will appreciated numerous modifications and variations therefrom. It is intended that all such modifications and variations fall within the spirit and scope of the invention.

1. A method of loading additional content data into storage, comprising:
(a) examining additional content data associated with main content data and loading persistent additional content data into the storage contiguously, the main content data being recorded on a recording medium; and
(b) loading at least one block of updatable additional content data included in the additional content data into a separate area of the storage from the area in which the persistent additional content data are loaded.

2. The method of claim 1, wherein the additional content data are read out from the recording medium.

3. The method of claim 1, wherein the additional content data are received from an external content provider server through a communication network.

4. The method of claim 1, wherein the additional content data include information on whether the additional content data is persistent or not.

5. The method of claim 1, wherein the persistent additional content data loaded in the storage are preserved until playback of the main content data recorded on the recording medium is completed.

6. The method of claim 1, wherein in the loading step (b), the at least one updatable additional content data block is loaded into the storage in contiguity with the persistent additional content data.

7. The method of claim 1, further comprising the step of (c) of, in response to completion of presentation of a last block of the updatable additional content data blocks loaded into the storage, deleting the last block and loading a new next updatable additional content data block to be presented subsequently into the storage means.

8. The method of claim 1, further comprising the step of (c) of, in response to beginning presentation of a last block of the updatable additional content data blocks loaded into the storage, deleting a one-block preceding updatable additional content data block of the last block, and loading a new next updatable additional content data block to be presented after the last block into the storage, during presentation of the last block.

9. The method of claim 1, further comprising the step of (c) of, in response to beginning presentation of a last block of the updatable additional content data blocks loaded into the storage, deleting a two-block preceding updatable additional content data block of the last block, and loading a new next updatable additional content data block to be presented after the last block into the storage, during presentation of the last block.

10. The method of claim 1, wherein the persistent additional content data include startup and menu pages composed of markup languages, markup page elements including style contents, fonts, logos, background images, sound effects, and/or animated logos.

11. The method of claim 1, wherein the storage is a memory.

12. An apparatus for loading additional content data, comprising:
a storage for storing the additional content data associated with main content data recorded on a recording medium; and
a controller for examining the additional content data, loading persistent additional content data into the storage contiguously, and storing at least one block of updatable additional content data included in the additional content data into a separate area of the storage from the area in which the persistent additional content data are loaded.

13. The apparatus of claim 12, wherein the additional content data are read out from the recording medium.

14. The apparatus of claim 12, wherein the additional content data are received from an external content provider server through a communication network.

15. The apparatus of claim 12, wherein the additional content data include information on whether the additional content data is persistent or not.

16. The apparatus of claim 12, wherein the persistent additional content data loaded in the storage are preserved until playback of the main content data is completed.

17. The apparatus of claim 12, wherein the controller loads the at least one updatable additional content data block into the storage in contiguity with the persistent additional content data.

18. The apparatus of claim 12, wherein, if presentation of a last block of the updatable additional content data blocks loaded into the storage is completed, the controller deletes the last block and loads a new next updatable additional content data block to be presented subsequently into the storage means.

19. The apparatus of claim 12, wherein, if presentation of a last block of the updatable additional content data blocks loaded into the storage is started, the controller deletes one-block preceding updatable additional content data block of the last block, and loads a new next updatable additional content data block to be presented after the last block into the storage, during presentation of the last block.

20. The apparatus of claim 12, wherein, if presentation of a last block of the updatable additional content data blocks loaded into the storage is started, the controller deletes a two-block preceding updatable additional content data block of the last block, and loads a new next updatable additional content data block to be presented after the last block into the storage, during presentation of the last block.

21. The apparatus of claim 12, wherein the persistent additional content data include startup and menu pages composed of markup languages, markup page elements including style contents, fonts, logos, background images, sound effects, and/or animated logos.

22. A recording medium, comprising:
main content data including at least video data; and
additional content data that are to be presented in synchronization with the main content data, wherein the additional content data include information on whether or not the additional content data is updatable after being loaded into a storage.

23. The recording medium of claim 22, wherein non-updatable additional content data pertaining to the additional content data is recorded thereon as one file.

24. The recording medium of claim 23, wherein the non-updatable additional content data are compressed in the file.
